(19) United States
(12) Patent Application Publication
(10) Pub. No.: US 2026/0114054 A1
(43) Pub. Date: Apr. 23, 2026

(54) SOLAR MODULE WITH THREE-TERMINAL TANDEM SOLAR CELLS

(71) Applicant: INSTITUT FÜR SOLARENERGIEFORSCHUNG GMBH, Emmerthal (DE)

(72) Inventors: Henning SCHULTE-HUXEL, Hannover (DE); Marc KÖNTGES, Hameln (DE); Robert WITTECK, Lakewood, CO (US)

(73) Assignee: INSTITUT FÜR SOLARENERGIEFORSCHUNG GMBH, Emmerthal (DE)

(21) Appl. No.: 19/113,610

(22) PCT Filed: Sep. 14, 2023
(86) PCT No.: PCT/EP2023/075347

§ 371 Date: Mar. 20, 2025

(30) Foreign Application Priority Data
Sep. 23, 2022 (DE) 10 2022 124 501.2

(51) Int. Cl. H10F 19/90; H02S 40/22; H10F 10/19

(52) U.S. Cl. CPC H10F 19/904; H02S 40/22; H10F 10/19

(57) ABSTRACT

A solar module includes a plurality of 3TT solar cells which are interconnected to form at least one string, and at least two current input connections at a current input of the solar module and/or at least two current output connections at a current output of the solar module. Each 3TT solar cell has a stack with a top cell and a bottom cell arranged below it. Each 3TT solar cell includes a top contact, a bottom contact and a center tap contact as terminal contacts. A first of the current input connections is connected to at least one of the terminal contacts of a first of the 3TT solar cells closest to the current input, and a second of the current input connections is connected to at least one of the terminal contacts of a second of the 3TT solar cells neighboring the first 3TT solar cell.

### FIELD

The present invention relates to a solar module comprising tandem solar cells.

### BACKGROUND

Solar modules serve to convert light, which is radiated in particular by the sun, into electrical energy. Solar modules of this kind are also referred to as photovoltaic modules or PV modules. In this case, a solar module comprises a plurality of solar cells that are interconnected in series and/or in parallel. The solar module furthermore conventionally comprises a current input connection and a current output connection, in order to be able to connect the solar module to further solar modules, in series and/or in parallel, to form a solar collector, and in order to ultimately be able to supply the electrical energy generated in the solar module to an external electrical circuit having consumers connected therein.

Conventionally, solar modules have typically made use of solar cells in which charge carrier pairs, generated by absorption of incident light, are separated at a single potential difference, for example generated by a p-n junction. In this case, a power or efficiency of the solar cells depends inter alia on the potential difference and thus on the (semiconductor) material used to generate the potential difference. In this case, the efficiency of the solar cells is limited inter alia by the fact that, depending on a band gap of the semiconductor material used, a low-energy portion of the radiated light may not be absorbed, and a high-energy portion may be converted into electrical energy only with significant energy losses.

In order to increase the efficiency of the solar cells, solar cells have been developed in which two or more partial solar cells are stacked on top of one another. Solar cells of this kind are referred to as tandem solar cells or sometimes also as multiple solar cells or stacked solar cells. In this case, the two partial solar cells differ with respect to their materials and thus with respect to their band gaps. In this case, a partial solar cell facing the incident light, which is also referred to as top cell, typically has a larger band gap and is therefore configured for absorbing and converting a high-energy portion of the irradiated light with relatively low energy losses. A further partial solar cell arranged therebelow, which is also referred to as the bottom cell, then has a smaller band gap and is therefore configured for absorbing and converting a low-energy portion of the irradiated light with relatively low losses.

Tandem solar cells are preferably constructed monolithically. That is to say that a tandem solar cell is designed as a single part in which all components, such as various semiconductor layers and contacts, are rigidly interconnected. For this purpose, for example a plurality of layers may be deposited on top of one another over the entire surface and/or in partial areas. In this case, the tandem solar cell comprises at least two, but, as explained below, in some implementations also three, four or more, terminal contacts. In this case, a terminal contact is understood to be an electrical contact on the tandem solar cell which is accessible from the outside and via which the solar cell or its partial solar cells may be electrically connected to other solar cells or their partial solar cells.

In this case, various connection configurations are known for tandem solar cells.

What are known as 2-terminal tandem solar cells, also referred to as 2TT solar cells, comprise just two terminal contacts, typically what is known as a top contact being provided on a front side and what is known as a bottom contact being provided on a rear side of the tandem solar cell. 2TT solar cells of this kind may be easily connected in a solar module, i.e. substantially in the manner of conventional non-tandem solar cells. However, the fact that an overall current flowing through the 2TT solar cell must be the same magnitude for both partial solar cells means that said current is limited by the weaker of the two partial solar cells. Accordingly, losses due to current mismatching regularly occur. A reason for this may on the one hand be that the band gaps of the two partial solar cells are not optimally selected due to technical boundary conditions and one partial solar cell generates a higher current than the other, the lower current of the weaker partial solar cell then limiting the overall current of the tandem solar cell. On the other hand, current mismatching effects may also occur in the case of an optimal selection of the band gaps, due to a change in the radiated light spectrum.

Losses due to current mismatching may be largely prevented if the individual partial solar cells of the tandem solar cells may be contacted and connected separately. For this purpose, a tandem solar cell may comprise four terminal contacts, i.e. be configured as what is known as a 4TT solar cell. In this case, each individual partial solar cell has its own two terminal contacts and may therefore be operated independently of the other partial solar cell, at its optimal operating point. However, for this purpose all the partial solar cells must be processed, contacted, and connected separately, which may require increased outlay and result in increased optical shading.

Quasi as a middle path between the 2TT solar cells and the 4TT solar cells, tandem solar cells comprising three terminal contacts have been developed, which are accordingly referred to as 3TT solar cells. In addition to a top contact and a bottom contact, 3TT solar cells comprise an additional terminal contact, which is referred to as the center tap contact. The center tap contact contacts both the top cell, as a second terminal contact in addition to the top contact, and the bottom cell, as a second terminal contact in addition to the bottom contact. As a result, 3TT solar cells allow on the one hand for an electrical connection within a solar module, in the case of which losses due to mismatching of the current may be significantly reduced. On the other hand, connecting the 3TT solar cells within the module may be less complex than in the case of 4TT solar cells, and/or losses due to optical shading on account of a plurality of terminal contacts may be less compared with the 4TT solar cells.

3TT solar cells and solar modules constructed therewith have been studied both theoretically and experimentally for a long time. Considerations and findings regarding their internal structure, and also their arrangement and connection in solar modules, are set out inter alia in the documents listed below, some of which are referenced in the following text:
[1] Sakai, S. and Umeno, M., “Theoretical analysis of new wavelength-division solar cells,” Journal of Applied Physics, vol. 51, no. 9, pp. 5018-5024, 1980.
[2] Gee, J.M., “A comparison of different module configurations for multi-band-gap solar cells,” Solar Cells, vol. 24, no. 1-2, pp. 147-155, 1988.
[3] Jimeno, J.C., Gutierrez, R., Fano, V., Habib, A., del Cañizo, C., Rasool, M.A., and Otaegi, A., “A 3 terminal parallel connected silicon tandem solar cell,” Energy Procedia, vol. 92, pp. 644-651, 2016.
[4] Nagashima, T., Okumura, K., Murata, K., and Kimura, Y., “Three-terminal tandem solar cells with a back-contact type bottom cell,” 2000. In Proceedings of the 28th IEEE PVSC, 1193-96. http://ieeexplore.ieee.org/servlet/opac?punumber=7320.
[5] McMahon, William; Schulte-Huxel, Henning; Buencuerpo, Jeronimo; Geisz, John; Young, Michelle; Klein, Talysa et al. (2021): Homogenous Voltage-Matched Strings Using Three-Terminal Tandem Solar Cells: Fundamentals and End Losses. In: IEEE J. Photovoltaics 11 (4), pp. 1078-1086. DOI: 10.1109/JPHOTOV.2021.3068325.
[6] Jimeno Cuesta, J., Luque Lopez, A., Recart Barañano, F., Lago Aurrekoetxea, R., Gutierrez Serrano, R., Varner, K., Ikaran Salegi, C. et al. “Photovoltaic device and photovoltaic panel,” WO/2011/045462, filed Oct. 14, 2010, issued Apr. 21, 2011.
[7] Borden, P.G. “Three-terminal solar cell circuit,” US4513168 A, filed 19.04.1984, issued 23.04.1985.
[8] H. Uzu, G. Koizumi, “SOLAR CELL MODULE”, WO/2020/196288, 19.03.2020, issued 01.10.2020.
[9] E.L. Warren et al., “A taxonomy for three-terminal tandem solar cells,” ACS Energy Lett., vol. 5, no. 4, pp. 1233-1242, Apr. 2020
[10] M. Zehender et al., “Module interconnection for the three-terminal heterojunction bipolar transistor solar cell”, AIP Conference Proceedings 2012, 040013 (2018); https://doi.org/10.1063/1.5053521, Published Online: 13 September 2018
[11] H. Schulte-Huxel et al., “String-Level Modelling of Two, Three, and Four Terminal Si-Based Tandem Modules”, IEEE JOURNAL OF PHOTOVOLTAICS, VOL. 8, NO. 5, SEPTEMBER 2018, pp. 1370-1375
[12] R. Witteck et al., “Partial shading of one solar cell in a photovoltaic module with 3-terminal cell interconnection”, Solar Energy Materials & Solar Cells 219 (2021) 110811

It has been observed that efficiencies or power yields may be suboptimal in the case of solar modules constructed with 3TT solar cells, i.e. may in particular be lower than would be expected on account of the efficiencies of the individual solar cells and the number of solar cells in a solar module.

### SUMMARY

There may therefore be a need for solar modules which allow for higher efficiencies or power yields. In particular, there may be a need for solar modules based on 3TT solar cells in which a high efficiency of the individual solar cells leads to a high efficiency of the overall solar module due to a suitably selected configuration of the solar cells within the solar module. Furthermore, there may be a need for a highly efficient solar collector comprising solar modules of this kind.

The mentioned needs may be met at least in part by the subject matter of one of the independent claims of the present application. Advantageous embodiments are specified in the dependent claims and in the following description and the drawings.

According to a first aspect of the present invention, a solar module is described which comprises a plurality of 3TT solar cells and at least two current input connections at a current input of the module and/or at least two current output connections at a current output of the module. In this case, the 3TT solar cells are interconnected to form at least one string. Each 3TT solar cell has a stack with a top cell and a bottom cell arranged below it, the top cell and the bottom cell differing from one another in terms of an electrical voltage generated when exposed to light. Each 3TT solar cell has three terminal contacts with a top contact, which makes electrical contact with a side of the top cell facing away from the bottom cell, a bottom contact, which makes electrical contact with a side of the bottom cell facing away from the top cell, and a center tap contact, which makes electrical contact with the 3TT solar cell at an interface between the top cell and the bottom cell. A first of the current input connections is connected at least to one of the terminal contacts of a first of the 3TT solar cells closest to the current input, and a second of the current input connections is connected at least to one of the terminal contacts of a second of the 3TT solar cells neighboring the first 3TT solar cell. Furthermore, a first of the current output connections is connected at least to one of the terminal contacts of a last of the 3TT solar cells closest to the current output, and a second of the current output connections is connected at least to one of the terminal contacts of a penultimate of the 3TT solar cells neighboring the last 3TT solar cell.

According to a second aspect of the present invention, a solar collector is described which comprises a plurality of solar modules according to an embodiment of the first aspect of the invention, in the case of neighboring solar modules in each case each of the current output connections of one of the solar modules being electrically connected to an associated one of the current input connections of the neighboring one of the solar modules.

By way of introduction, a basic concept regarding embodiments of the invention described herein will be briefly explained, this explanation being intended to be interpreted as merely a general summary and not limiting the invention:

The present invention in particular describes a solar module in which, on account of a special type of arrangement and connection of the 3TT solar cells received therein, losses, in particular what are known as string-end losses, as occur in conventional solar modules in which the 3TT solar cells are arranged and connected in a conventional manner, may be largely prevented. As will be explained in more detail below, in this case a main feature of the solar module set out herein may be considered to be the fact that the solar module does not, as is usually typical in the case of conventional solar modules, comprise just one single current input connection and one single current output connection, but rather in each case comprises two or more such current input connections and current output connections, and in this case these connections are connected to the 3TT solar cells within the solar module in a specific manner. Owing to the special type of connection and the plurality of current input connections and current output connections, it is made possible, in this case, for string-end losses by partial solar cells, which, on account of the connection, do not or do not optimally contribute to the efficiency of the module, are no longer caused on each connected solar cell string, i.e. at least once in each solar module. Instead, a plurality of solar modules may be interconnected in such a way that corresponding end losses are caused just once in the entire plurality of solar modules, and thus have a significantly reduced influence on the overall efficiency of a solar collector. Furthermore, an embodiment of a solar module comprising 3TT solar cells is described in which a suitable connection of bypass diodes ensures the reliable operation of the solar module and at the same time makes it possible to prevent the above-mentioned end losses.

Possible implementations and advantages of embodiments of the solar module, and of a method for producing said module, are described in more detail below:

A solar module, as described here, comprises a plurality of solar cells in the form of 3TT solar cells. For example, the solar module typically comprises more than ten solar cells, usually more than 50 solar cells, but generally fewer than 300 solar cells, usually fewer than 150 solar cells. Each individual solar cell is a two-dimensionally formed diode, a surface area typically being between 10 cm² and 1000 cm², usually between 100 cm² and 500 cm². A thickness of a solar cell is typically in the range of between 10 μm and 1000 μm, usually between 50 μm and 400 μm. At least a part of the solar cell may be formed based on a crystalline, i.e. monocrystalline, multicrystalline or polycrystalline, semiconductor substrate, such as a silicon wafer. Alternatively or in addition, a part of the solar cell may be formed with amorphous semiconductor material, for example in the form of one or more thin films.

The solar cells are connected to form one or more strings. In this case, the entire solar cells or the partial solar cells forming said solar cells may be interconnected in series and/or in parallel. In this case, a string is understood to be a smallest unit of a plurality of interconnected solar cells, it being possible for the entire solar module to comprise a plurality of such strings interconnected in series and/or in parallel. In this case, a number of solar cells that may be combined in a string may depend on various influencing factors. In particular, this number is typically selected such that an electrical voltage generated by the string upon illumination does not exceed a reverse electric strength of each individual solar cell in the string. Typically, such strings comprise between three and 50 solar cells connected in series, usually between six and 30 solar cells connected in series.

The 3TT solar cells installed in the solar module are made up of a first partial solar cell and a second partial solar cell. The first partial solar cell is arranged on a side of the solar cell facing the incident light during use, which side is considered the top side, and therefore said first partial solar cell is referred to as the top cell. The second partial solar cell is arranged below the first partial solar cell and is therefore referred to as the bottom cell. Each of the partial solar cells may in turn have a single p-n junction or, when special cell designs are used, a plurality of p-n junctions, which are preferably located one behind the other along the direction of incident light.

The top cell and the bottom cell differ with respect to the semiconductor materials of which they are formed. For example, the semiconductor material of the top cell typically has a larger energy band gap than that of the bottom cell, it being possible for the two band gaps to differ from one another, in amount, by more than 20%, preferably more than 40%, or even more than 80%. Owing to the different band gaps, different electrical voltages are established in the two partial solar cells, upon illumination, at a potential difference (for example owing to a respective p-n junction) formed therein in each case by suitable local doping. In other words, the off-load voltages (which are sometimes also referred to as open circuit voltages V_{OC}) in the top cell and the bottom cell differ significantly. For example, the V_{OC} of the top cell may be 30% or more, 50% or more, or even 100% or more greater than that of the bottom cell.

Each 3TT solar cell comprises exactly three terminal contacts, via which it is connected to other 3TT solar cells. In this case, a terminal contact is generally formed by an electrically conductive layer, such as a metal layer, attached to the solar cell or integrated into the solar cell. In this case, a terminal contact may be formed with a single layer, but the terminal contacts may also be made up of a plurality of partial regions or partial layers.

The three terminal contacts may be denoted according to a convention as was introduced by Warren et al. (see document [9] in the list of documents cited in the introduction to the description). In this case, a first contact is typically arranged on a front side surface of the solar cell facing the incident light, and electrically contacts the side of the top cell that faces away from the bottom cell (“electrically contact” being intended to be understood herein, in general, as direct electrical contact, i.e. without interposition of other electrical components, i.e. in particular an ohmic contact). The first contact is referred to herein as the top contact, but, according to the convention by Warren, may also be referred to as the T-contact (with “T” for top). A second contact is typically arranged on a rear side surface of the solar cell facing away from the incident light, and electrically contacts the side of the bottom cell that faces away from the top cell. The second contact is referred to herein as the bottom contact, but, according to the convention by Warren, may also be referred to as the R-contact (with “R” for raiz or root). A third contact may for example be arranged in a plane between the top cell and the bottom cell. As set out in more detail below, the third contact may, however, also be arranged, spatially, on the rear side surface of the solar cell, it being possible for the bottom cell and the third contact to be configured such that an electrical current prevailing at an interface between the top cell and the bottom cell to be discharged via the third contact. In both cases, the third contact electrically contacts the interface between the top cell and the bottom cell. In this case, it electrically contacts a side of the bottom cell which is opposite the side contacted by the bottom contact and has an opposite polarity from the region of the bottom cell contacted by the bottom contact, such that a voltage generated at the bottom cell may be tapped via the bottom contact and the third contact. Furthermore, the third contact electrically contacts a side of the top cell which is opposite the side contacted by the top contact and has an opposite polarity from the region of the top cell contacted by the top contact, such that a voltage generated at the top cell may be tapped via the top contact and the third contact. The third contact is referred to herein as the center tap contact, but, according to the convention by Warren, may also be referred to as the Z-contact (with “Z” for zusaetzlich (in English: “extra”or “additional”)).

In conventional solar modules, each individual solar module typically comprises just one current input connection and just one current output connection, via which the solar cells integrated in the solar module may be connected to an external electrical circuit. In this case, a plurality of solar modules may in each case be interconnected in series and/or in parallel, via their individual current input connections and current output connections, in order to form, overall, a solar collector.

In contrast thereto, the solar module described herein is intended to comprise at least two current input connections and/or at least two current output connections. Preferably, each solar module should comprise at least two current input connections and two current output connections. At least theoretically, however, it is conceivable that a solar module which serves as a first solar module within a solar collector may comprise just one current input connection but two current output connections, or a solar module which serves as a last solar module within a solar collector may comprise two current input connections but just one current output connection.

In this case, the current input connections and current output connections are electrically connected in a special manner to the terminal contacts of the various solar cells within the solar module.

In particular, a first current input connection is electrically connected at least to one of the terminal contacts of the solar cell that is closest to the current input in the solar module, i.e. which has no further solar cell upstream on the current input side and which may therefore be considered the first solar cell of the solar module. A second current input connection is electrically connected at least to one of the terminal contacts of the solar cell which neighbors the first solar cell, i.e. to the second solar cell within the solar module. In this case, the first and the second solar cell are components of the same string. Preferably, the first current input connection is directly electrically connected only to the first solar cell. The second current input connection may be directly electrically connected only to the second solar cell. In addition, the second current input connection may also be connected to one of the terminal contacts of the first solar cell, this terminal contact differing, however, from the terminal contact to which the first current input connection is connected. Accordingly, there is no direct ohmic electrical connection between the first and the second current input connection.

In a similar manner, a first current output connection is connected to at least one of the terminal contacts of a last solar cell closest to the current output, and a second current output connection is connected to at least one of the terminal contacts of a penultimate solar cell neighboring the last solar cell. In this case, the last and the penultimate solar cell are components of the same string. In this case, too, preferably the first current output connection is directly electrically connected only to the last solar cell of the solar module. The second current output connection may be directly electrically connected only to the penultimate solar cell. In addition, the second current output connection may also be connected to one of the terminal contacts of the last solar cell, this terminal contact differing, however, from the terminal contact to which the first current output connection is connected. Accordingly, there is no direct ohmic electrical connection between the first and the second current output connection.

Providing at least two electrically separate current input connections and/or at least two separate current output connections, as well as the special manner in which these connections are connected to the various solar cells within the solar module, makes it possible, inter alia, for the different partial solar cells, i.e. the top cells and the bottom cells to be interconnected within the solar module in an advantageous manner such that almost all the partial solar cells may be operated optimally within an overall solar collector having a plurality of solar modules, i.e. contribute to an overall efficiency of the solar collector. In particular, string-end losses, as typically occur, in the case of conventional solar modules comprising 3TT solar cells, in each individual solar module of a solar collector or even on each individual string, may be largely prevented or it is possible to limit their occurrence on a first solar module and/or a last solar module within a solar collector comprising a plurality of solar modules. This is explained herein in more detail below, with reference to specific embodiments.

According to one embodiment, the top cell and the bottom cell of each of the 3TT solar cells are arranged in an r-type configuration in reverse polarity. Furthermore, the first current input connection is connected to the center tap contact of the first 3TT solar cell and the second current input connection is connected to the center tap contact of the second solar cell. Alternatively or in addition, the first current output connection is connected to the top contact of the last 3TT solar cell and the second current output connection is connected to the top contact of the penultimate 3TT solar cell.

In other words, in this embodiment the top cell and the bottom cell of a 3TT solar cell are oriented with opposing polarity, i.e. for example the forward direction of the top cell is directed from the center tap contact towards the top contact, and the forward direction of the bottom cell is directed from the center tap contact towards the bottom contact. An embodiment of this kind is also referred to as an r-type configuration, “r” standing for “reverse.” In contrast thereto, in the case of what is known as an s-type configuration the top solar cell and the bottom solar cell are oriented identically and thus connected in series. In the case of the solar modules described herein, the r-type configuration allows for particularly advantageous connection of the 3TT solar cells to one another and to the at least two current input connections or at least two current output connections, respectively.

In particular, in this case, the first current input connection may preferably be electrically contacted only by the center tap contact of the first 3TT solar cell of the solar module. The second current input connection is then brought into electrical contact with the center tap contact of the second 3TT solar cell of the solar module, it being possible for said second current input connection to additionally be brought into electrical contact with the bottom contact of the first 3TT solar cell. Alternatively or in addition, the first current output connection is preferably brought into electrical contact only with the top contact of the last 3TT solar cell of the solar module. The second current output connection is then brought into electrical contact with the top contact of the penultimate 3TT solar cell of the solar module, it being possible for said second current output connection to additionally be brought into electrical contact with the bottom contact of the last 3TT solar cell of the solar module.

The described r-type configuration together with the special manner of connecting the connections makes it possible to connect the 3TT solar cells to one another and to the plurality of input and output connections in an advantageous manner, in particular in a manner requiring relatively few electrical lines, in such a way that occurrence of losses, in particular occurrence of string-end losses, may be largely limited.

This applies in particular for the case where the electrical voltages generated by the top cells and the electrical voltages generated by the bottom cells are in a particular ratio to one another.

For example, according to one embodiment, the electrical voltage of the top cell generated when exposed to light, and the electrical voltage of the bottom cell generated when exposed to light, may be substantially in a ratio of m to n. In this case, m and n are natural numbers. In this case “substantially” may for example be understood to mean that the ratio of the actually occurring electrical voltages in the top cell and the bottom cell differ from a ratio (m:n) for example by less than 25%, preferably less than 15%, more preferably less than 5%. In this case, in each case n top cells connected in series may be connected in parallel with m bottom cells connected in series.

In other words, the top cell and the bottom cell may be configured, for example due to a suitable selection of materials and/or dopings used for their production, such that their electrical voltages generated upon joint illumination, i.e. preferably their electrical voltages Vₘₚₚ at the point of maximum power, are substantially in a whole number ratio to one another. Accordingly, the n top cells connected in series may generate substantially the same voltage, when illuminated, as the m series-connected bottom cells connected in parallel therewith. The described adjustment of the voltages between the partial solar cells is also referred to as voltage-matching of the strings (voltage-matched strings).

In this case, according to a specified embodiment the following may be the case: m≥2 and n≥1. A number of the current input connections and/or a number of the current output connections then corresponds (in the case of an r-type configuration) to a larger of the two values m and n, or (in the case of an s-type configuration), is greater than the larger of the two values m and n.

In other words, a number of the current input connections and/or current output connections provided on the solar module may correlate with the way in which the top cells and the bottom cells are matched to one another with respect to the electrical voltages they generate, and may thus be connected in a matched manner, in groups consisting of a plurality of series-connected top cells, in parallel to groups of a plurality of series-connected bottom cells.

According to a specified embodiment, for example the following may be the case: m=2 and n=1. In this case, with the exception of the last 3TT solar cell, each bottom contact of a solar cell may be connected to the center tap contact of the neighboring next 3TT solar cell, and, with the exception of the last and the penultimate 3TT solar cell, each top contact of a solar cell may be connected to the center tap contact of the next but one following 3TT solar cell.

Such matching of the voltages generated by the top cells and bottom cells in the ratio (2:1) together with the described interconnection of the top cells and bottom cells of the plurality of 3TT solar cells may allow for a particularly simple overall connection within the solar module with simultaneously high efficiency, owing to a prevention of losses, in particular end losses.

According to one embodiment, in each of the strings a first bypass diode is connected in parallel with the 3TT solar cells of the string. Furthermore, in each of the strings a second bypass diode is connected in parallel with the top cell of a last 3TT solar cell of the string.

Like all diodes, bypass diodes allow a substantial current flow exclusively in one direction, i.e. in their forward direction. In the case of solar modules, bypass diodes are typically connected in antiparallel to the solar cells e.g. of a string, such that in the normal operating state, i.e. when all the solar cells are functioning correctly and generating current, they are polarized in the reverse direction. However, if one (or more) of the solar cells does not deliver any current, for example on account of shading, it acts like an electrical load. The current generated by the other solar cells would have to flow over this load, whereby significant heat may arise and what are known as hotspots may result. Moreover, the overall current flowing through a solar module generally depends on the weakest solar cell within the solar module, and therefore a single shaded solar cell could significantly limit the efficiency of the solar module. Therefore, in order to prevent hotspots and reduced yields, in solar modules bypass diodes are typically connected in anti-parallel to strings consisting of solar cells interconnected in series. In this case, a cut-off voltage of the bypass diode corresponds approximately to an off-load voltage of the solar cells connected in the string.

In the case of the solar modules of 3TT solar cells described herein, as explained above, the individual top cells and bottom cells of the plurality of 3TT solar cells may be connected such that in each case a first number of top cells is interconnected in series and a different second number of bottom cells is also connected in series, both series circuits being connected in parallel with one another. In this case, for example the top cells of the 3TT solar cells may not be connected in series, in each case, to the top cell of a directly neighboring 3TT solar cell, but rather only to the top cell of a next but one 3TT solar cell. In this case, a first bypass diode may be connected in parallel with the 3TT solar cells of a string. However, in the case of the described connection the top cell of the last 3TT solar cell of the string is not protected by said first bypass diode. Accordingly, it is advantageous to provide an individual, second bypass diode for said top cell, which bypass diode is connected in parallel with said top cell.

In principle, a second bypass diode of this kind may have different properties from the first bypass diode, since it merely has to protect a single top cell. For example, the off-load voltage of the second bypass diode may be lower than that of the first bypass diode. However, it may also be provided to configure all the bypass diodes received in the solar module identically.

According to a specified embodiment, the first bypass diode may be electrically connected on the one hand to the center tap contact of the first 3TT solar cell of the string and on the other hand to the bottom contact or the top contact of the last 3TT solar cell of the string. In this case, furthermore the second bypass diode may be electrically connected on the one hand to the top contact or the bottom contact of the last 3TT solar cell of the string and on the other hand to the center tap contact of the last 3TT solar cell of the string.

Such a type of connection of the first and second bypass diodes may, as described below with reference to a specific embodiment, be advantageous in particular for an embodiment of the solar module in which the 3TT solar cells are configured in an r-type configuration and are matched to one another in the ratio (2:1) with respect to the voltages of their top cells and bottom cells.

According to an alternative embodiment, the solar module may comprise at least one bypass diode which is connected across strings, the bypass diode connected across strings being connected on the one hand to a 3TT solar cell upstream of the last 3TT solar cell (i.e. for example a penultimate 3TT solar cell) of a neighboring sub-string and on the other hand to the last solar cell of the sub-string to be protected.

In other words, in the solar module a connection of bypass diodes to the 3TT solar cells may be configured such that at least a last 3TT solar cell in one of the sub-strings is connected to two bypass diodes, specifically the bypass diode associated with the sub-string in question and connected in parallel therewith, and the bypass diode associated with a neighboring sub-string. In this case, the bypass diodes may be connected to the 3TT solar cell in question in such a way that one of the two bypass diodes protects the bottom cell and at least the other of the two bypass diodes protects the top cell of said 3TT solar cell. In this way, it is preferably possible to avoid providing a separate bypass diode merely for protecting a single top or bottom cell of a single 3TT solar cell, as has been discussed further above with respect to the second bypass diode.

According to an alternative embodiment, the solar module may have at least one further current input connection and/or at least one further current output connection. In this case, at least one bypass diode to be connected across modules is received in the solar module. In this case, the bypass diode to be connected across modules may be connected on the one hand to the further current input connection and on the other hand to one of the terminal contacts, in particular to the bottom contact, of one of the 3TT solar cells in the solar module. Alternatively or in addition, the center tap contact of the last 3TT solar cell of the solar module may be connected to the further current output connection.

In this embodiment of the solar module, the above-described provision of a second bypass diode for protecting the top cell of a last 3TT solar cell in a string may be omitted. Instead, this top cell may also be protected by the or one of the first bypass diodes of the following string, i.e. a bypass diode connected in this way may act across strings. For this purpose, the following first bypass diode contacts the last top cell of the preceding string, in that, for example in the case of the r-type configuration, it contacts the center contact of the last cell in the strand. However, if the top cell to be protected is that of the last 3TT solar cell not only within one of a plurality of strings in the solar module but rather the very last 3TT solar cell in the entire solar module, this may not be protected by a first bypass diode from the same solar module. Instead, this top cell is also protected with the aid of a first bypass diode of a neighboring solar module. In order to allow for a connection of the bypass diodes across modules, for this purpose, at least one further current input connection and/or at least one further current output connection is provided on the solar module, via which connection the mentioned top cell may be connected to the first bypass diode in a neighboring solar module. An illustrative example of such an embodiment of the solar module is set out below.

According to a further specified embodiment, plural 3TT solar cells are arranged laterally side-by-side over an entire width of the solar module and are electrically connected to form a sub-string. In this case, the first bypass diode and, if present, the second bypass diode are each arranged laterally beside the sub-string.

In other words, the solar module may be configured, with regard to a geometric arrangement of the 3TT solar cells received therein, in such a way that a plurality of the solar cells which form a sub-string are arranged laterally side-by-side along the entire width of the solar module. Accordingly, the sub-string contains a relatively large number of solar cells connected in series.

This type of connection in cell-rich sub-strings is suitable in particular for the case where the individual partial solar cells each have a relatively high reverse electric strength. In this case, it may be advantageous to arrange the first and the second bypass diode in each case laterally beside the sub-string, i.e. on an outside edge of the solar module. There, the bypass diodes may be particularly easily accessible and/or arranged in a space-saving manner, for example in the region of a frame of the solar module that locally covers the edge of the solar module.

According to an alternative specified embodiment, plural 3TT solar cells are arranged laterally side-by-side over a first half of a width of the solar module and are electrically connected to form a first sub-string, and plural other 3TT solar cells are arranged laterally side-by-side over a second half of the width of the solar module and are electrically connected to form a second sub-string. In this case, the first sub-string and the second sub-string are connected in parallel with one another. Furthermore, the first bypass diode and, if present, the second bypass diode are each arranged spatially between the first sub-string and the second sub-string.

In other words, the solar module may be configured, with respect to the geometric arrangement of the solar cells arranged therein, such that in each case only a relatively small number of solar cells is connected to form a sub-string. In this case, the solar cells connected to form a sub-string are arranged geometrically laterally side-by-side in such a way that they extend only over half the width of the solar module. Therefore, over the entire width of the solar module two spatially neighboring sub-strings may be arranged side-by-side. In this case, the two sub-strings are preferably connected in parallel with one another.

Since in the case of such a type of connection the number of solar cells within a sub-string is relatively small, this embodiment is suitable in particular for the case where at least some of the partial solar cells have a relatively low reverse electric strength. In this case, it may be advantageous to arrange the first and the second bypass diode in each case geometrically between the first sub-string and the second sub-string. The bypass diodes may thus be arranged for example in or close to a geometric center of the solar module. In this case, a single first bypass diode may be provided for the two sub-strings connected in parallel, which diode is in turn connected in parallel with the two sub-strings. Furthermore, an individual second bypass diode may be provided for each of the two sub-strings, one second bypass diode being connected in anti-parallel to the top cell of the last 3TT solar cell in one of the two sub-strings and a further second bypass diode being connected in antiparallel to the top cell of the last 3TT solar cell in the other of the two sub-strings. Overall, owing to the central arrangement of the bypass diodes between the sub-strings, a favorable overall connection in the solar module having for example short connection distances and correspondingly low electrical resistance losses may be achieved.

According to a further specified embodiment, the first and, if present, the second bypass diode may be received in a common diode box.

In this case, a diode box may for example be a housing in which the bypass diodes may be received and by which the bypass diodes may be protected, for example against environmental influences. Since both bypass diodes may be received in a common diode box, the number of diode boxes required may be kept low. Furthermore, the design of the solar module with respect to the diode boxes to be provided therein may be the same as or similar to that of conventional solar modules in which there is just one bypass diode per solar cell string. Accordingly, the solar modules may be produced and/or mounted, with respect to their diode boxes, in the same way as conventional solar modules.

According to one embodiment, the top cell is a perovskite solar cell and the bottom cell is a silicon solar cell.

Silicon solar cells are known for their durability, reliability, and high efficiency. For example, silicon solar cells are commercially available that may provide an efficiency of significantly over 20% and may reliably provide a service life of 20 years or more. However, the efficiency of silicon solar cells is limited inter alia in that silicon has a relatively small band gap, and therefore high-energy light may generally be converted into electrical energy only with relatively high energy losses in the form of generation of heat.

In recent times, perovskite solar cells have been developed, which may now also provide a high efficiency, a durability and reliability depending significantly on the exact composition of the perovskite used. Perovskite generally have a significantly greater band gap than for example silicon, and therefore solar cells formed therefrom are destined for low-loss absorption of high-energy light.

Accordingly, perovskite solar cells are excellently suited to serve in tandem solar cells as a partner for silicon solar cells and to be used there as the top cell. In this case, the exact composition of the perovskites used correlates strongly with their band gap, and therefore indirectly with the off-load voltage delivered by the perovskite solar cell.

In the case of the approach described herein for a solar collector, perovskite solar cells may be used as top cells in the 3TT solar cells, and in this case be optimized for example with respect to their durability and reliability. In this case, the electrical voltage of the top cells that occurs upon illumination depends on the perovskites used. Depending on the electrical voltage arising, the connections within the solar module, and the number of current input connections and current output connections, may then be adjusted, as described herein, in order to be able to achieve a favorable voltage matching between the top cells and the bottom cells within the solar module.

According to one embodiment, the bottom solar cell may be a rear contact solar cell, in which terminal contacts of both polarities are arranged in an interdigitated manner on a rear side of the bottom solar cell facing away from the top solar cell, one of the terminal contacts of the bottom solar cell acting as the center tap contact.

Rear contact solar cells in which contacts of both polarities are arranged in an interdigitated manner on a rear side of a semiconductor substrate facing away from the light have long been known and are sometimes also referred to as IBC solar cells (interdigitated back contact). In the case of suitable adjustment of the structures used in them, in particular the layer thicknesses, such rear contact solar cells may be adjusted such that they function, in a tandem solar cell, as the bottom cell, and, therein, the two types of contacts not only serve for extracting the generated current from the bottom cell but rather one of the contacts is furthermore electrically connected, for example via tunnel contacts, to the top cell, in such a way that the current generated in the top cell may also be extracted thereby, together with the top contact. In this case, the mentioned contact acts as a center tap contact for the 3TT solar cell, but is not arranged spatially centrally between the top cell and the bottom cell, but rather on the rear side of the bottom cell. Corresponding concepts have already been proposed, for example in document [4] cited in the introduction to the description. Since the center tap contact is provided on the rear side of the bottom cell, this may both be produced comparatively simply and also be contacted from the outside. As a result, production of the 3TT solar cells and/or connection of the 3TT solar cells within the solar module may be significantly simplified.

Embodiments of the solar modules described herein may be used for forming, therefrom, a solar collector according to the second aspect of the present invention. The property that each solar module in this case comprises at least two current input connections and/or two current output connections may in this case be used for interconnecting neighboring solar modules in such a way that losses, such as string-end losses, as occur in the case of conventionally designed and connected solar modules comprising 3TT solar cells, are largely prevented. For this purpose, each of the current output connections of one of the solar modules is electrically connected to an associated one of the current input connections of the neighboring one of the solar modules. In other words, for example the first current output of a solar module is connected to the first current input of the neighboring solar module, and the second current output of the solar module is connected to the second current input of the neighboring solar module.

As a result, as explained in more detail below with reference to an embodiment, it is possible to prevent the situation where, in each of the solar modules, at least one first 3TT solar cell closest to the current input and/or one last 3TT solar cell closest to the current output may not be operated optimally, and accordingly the mentioned end losses occur. Instead, on account of the special connection, proposed herein, between neighboring solar modules via the at least two output and input connections such end losses no longer occur in each individual solar module but rather, ideally, only in a first solar module and/or a last solar module of the overall solar collector. Accordingly, the influence of these end losses on the efficiency of the overall solar collector may be significantly reduced.

According to one embodiment, with the exception of the current input connections of a first of the solar modules and the current output connections of a last of the solar modules, the current input connections of each of the solar modules are electrically separated from one another and the current output connections of each of the solar modules are also electrically separated from one another.

Furthermore, according to one embodiment, in the case of a first of the solar modules the at least two current input connections are electrically short-circuited with one another or interconnected, and/or in the case of a last of the solar modules the at least two current output connections are electrically short-circuited with one another or interconnected.

In other words, each of the current input connections of a solar module is electrically connected to just one of the current output connections of the neighboring solar module, but not to the other current input connection of the same solar module or the other current output connection of the neighboring solar module. This preferably applies for all the solar modules of the solar collector, with the exception of the first solar module and the last solar module. In the case of these two solar modules, which are located at opposite ends of the series connection of solar modules within the solar collector, the current input connections of the first solar module and the current output connections of the last solar module serve for connecting the entire solar collector to a single external electrical circuit. Accordingly, these two “extremal” current input connections and/or current output connections are electrically interconnected. Accordingly, end losses may not be avoided at the first solar module and the last solar module, but are prevented at all solar modules therebetween.

It is noted that possible advantages and configurations of embodiments of the invention are described herein partly with reference to a solar module according to the invention or partly with reference to a solar collector made up of a plurality of such solar modules. A person skilled in the art will recognize that the described features may be transferred, adjusted, exchanged, or modified in a suitable manner in order to arrive at further embodiments of the invention.

### BRIEF DESCRIPTION OF THE DRAWINGS

Embodiments of the invention are described in the following with reference to the accompanying drawings, neither the drawings nor the description being intended to be interpreted as limiting the invention.

FIG. 1(a)-(d) illustrate a connection of 2TT solar cells, 4TT solar cells, 3TT solar cells in an s-type configuration, and 3TT solar cells in an r-type configuration.

FIG. 2(a) is a schematic sectional view of a 3TT solar cell comprising a rear contact solar cell as the bottom cell in an r-type configuration.

FIG. 2(b) is a schematic sectional view of a 3TT solar cell comprising a rear contact solar cell as the bottom cell in an s-type configuration.

FIG. 3 illustrates a conventional connection of 3TT solar cells in an r-type configuration with occurring end losses.

FIG. 4 illustrates a connection in a solar module according to the invention comprising 3TT solar cells in an r-type configuration each having two separate current input and output connections and a plurality of first and second bypass diodes.

FIG. 5 shows two solar modules connected to form a solar collector according to the invention.

FIG. 6 illustrates a connection in a solar module according to the invention comprising 3TT solar cells in an r-type configuration having bypass diodes connected across strings and each having three separate current input and output connections for allowing a connection of a bypass diode across modules.

FIG. 7 shows a geometric arrangement and connection of bypass diodes in a solar module according to the invention.

FIG. 8 shows an alternative geometric arrangement and connection of bypass diodes in a further solar module according to the invention.

The figures are merely schematic and not to scale. In particular, it is noted that the dimensions shown in the figures are not reproduced realistically, but rather are intended merely to illustrate fundamental principles. The same reference signs in the different figures denote identical or identically acting features.

### DETAILED DESCRIPTION

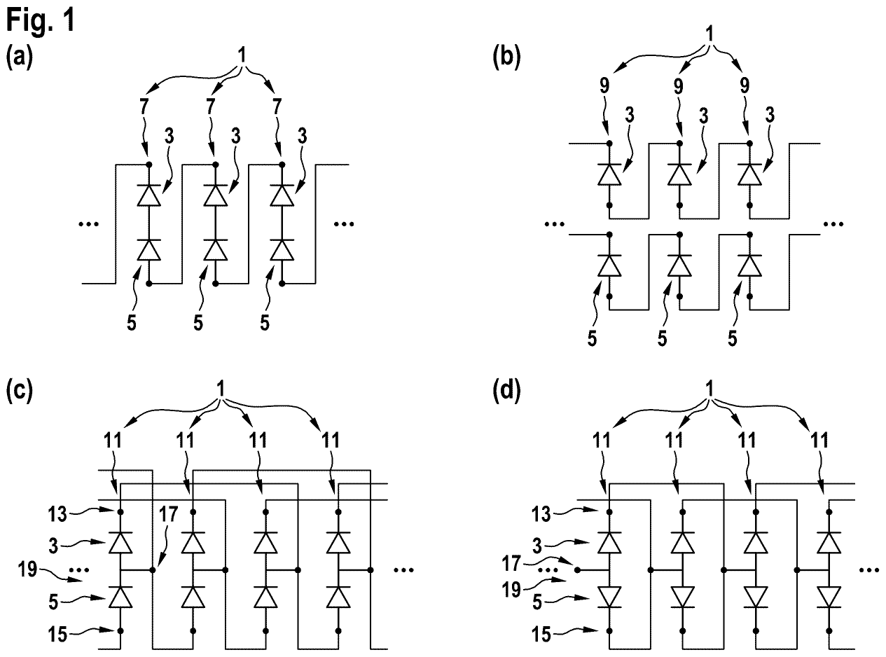

Multiple, stacked or tandem solar cells 1, as are shown in various embodiments and connections in FIG. 1(a)-(d) as portions of a respective solar module 19, offer the possibility, by absorption of different spectral portions in partial cells lying one on top of the other in the form of a top cell 3 and a bottom cell 5, of achieving significantly higher efficiencies compared with solar cells having just one p-n junction.

If, as shown in FIG. 1(a), the partial solar cells 3, 5 are stacked on top of one another and connected in series to form 2-terminal tandem solar cells 7 (i.e. a cell having two connections or contacts), losses may occur due to current mismatching. Reasons for this are on the one hand that the band gaps of the two partial solar cells 3, 5 are usually not optimally selected due to technical boundary conditions and one partial solar cell generates a higher current than the other. The lower partial cell current then limiting the overall current of the 2TT solar cell. On the other hand, current mismatching effects may also occur in the case of an optimal selection of the band gaps, for example due to a change in the irradiated spectrum.

Losses due to mismatching of the current may be prevented if the individual partial solar cells 3, 5 are, as shown in FIG. 1(b), contacted and connected separately. For this purpose, a tandem solar cell 1 comprises four connections or contacts, i.e. in each case two connections for each partial solar cell 3, 5, and is therefore referred to as a 4-terminal tandem solar cell 9. In this case, the respective partial solar cells 3, 5 may operate at the optimal operating point. For this purpose, however, all the partial solar cells must be processed, contacted, and connected separately, which generally means increased outlay and optical shading.

Tandem solar cells 1 having three terminal contacts, i.e. 3TT solar cells 11, as are shown in FIGS. 1(c) and 1(d), make it possible to significantly reduce losses due to mismatching of the current. In this case, FIG. 1(c) shows what is known as an s-type configuration, in which the top cell 3 and the bottom cell 5 are polarized in the same direction and are thus connected in series. FIG. 1(d) shows what is known as an r-type configuration, in which the top cell 3 and the bottom cell 5 are poled in the opposite direction, i.e. “reverse”.

An attractive variant of a 3TT solar cell 11 is the use of a bottom cell 5 as an IBC solar cell having two rear contacts arranged interdigitated within one another and one contact on the front side that allows for contact to the top cell 3. A design for such a 3TT solar cell 11 is explained for example in the document [4] cited in the introduction to the description.

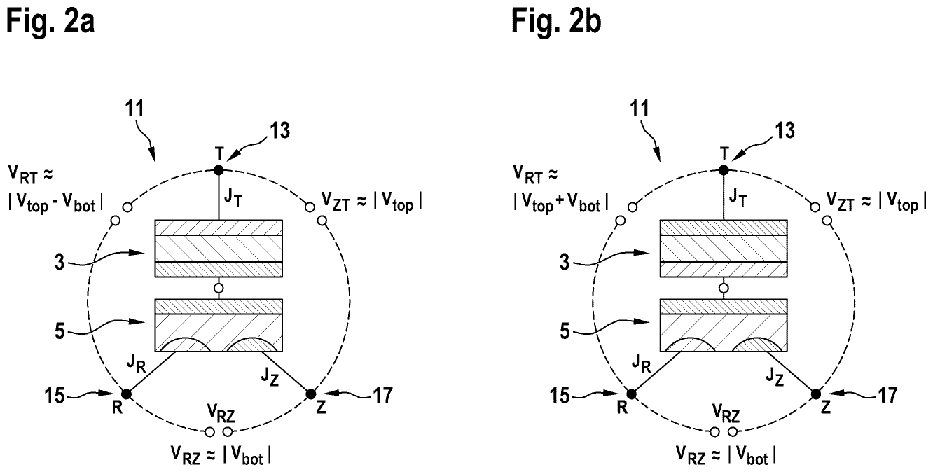

FIGS. 2(a) and 2(b) show embodiments of a 3TT solar cell 11 of this kind, a contact arrangement and designation being performed in accordance with the convention according to Warren et al. (see document [9] cited in the introduction to the description). In this case, identical dopings are in each case reproduced by a same manner of shading in the figures. The 3TT solar cells may be produced in different types, which may be categorized into a “reverse” connection, i.e. as an r-type configuration as shown in FIG. 2(a), and “series” connection, i.e. as an s-type configuration as shown in FIG. 2(b). Owing to the simpler connection, in the following primarily the “reverse” variant will be discussed. The terminal contacts of the 3TT solar cells 11 are designated according to their properties. The top contact 13 or T-contact is the single accessible contact on the top cell 3. In this case, the top contact 13 contacts the side of the top cell 3 facing away from the bottom cell 5. The bottom contact 15 or R-contact (for “raiz” or “root”) is the contact of the two rear-side contacts of the bottom cell 5 having the opposing polarity of the front-side contact of the bottom cell. In this case, the bottom contact 15 contacts the side of the bottom cell 5 facing away from the top cell 3. The center tap contact 17 or Z-contact (for “zusaetzlich”) is the rear contact having the same polarity of the bottom cell front side, i.e. the additional contact, in order to extract the charge carriers. The center tap contact thus electrically contacts a side of the bottom cell 5 which is opposite the side contacted by the bottom contact 15 and has an opposite polarity relative thereto. Thus, the center tap contact 17 is also capable of extracting charge carriers, which were separated in the top cell 3, from the interface between the top cell 3 and the bottom cell 5. In this case, the center tap contact 17 may be arranged geometrically between the top cell 3 and the bottom cell 5, in the case of a rear-side contacting, however, similarly to the case of an IBC solar cell, the center tap contact 17 may alternatively also be arranged geometrically on the rear side of the bottom cell 5, i.e. laterally adjacently to the bottom contact 15, and in this case act as being electrically connected to the interface between the top cell 3 and the bottom cell 5.

FIGS. 2(a) and 2(b) additionally show the electrical voltages prevailing between the various terminal contacts 13, 15, 17. In this case, Vₜₒₚ is the voltage generated by the top cell 3, and V_{bot} is the voltage generated by the bottom cell 5. V_{RT} is the voltage prevailing between the bottom contact 15 and the top contact 13, V_{ZT} is the voltage prevailing between the center tap contact 17 and the top contact 13, and V_{RZ} is the voltage prevailing between the bottom contact 15 and the center tap contact 17.

Advantages of 3TT solar cells consist inter alia in that
(i) solar modules formed thereby are to be operated as bifacial tandem modules in free field, since the top and bottom solar cell do not have to have the same current. Thus, a significant market entry hurdle is avoided, since the extra yield of tandem modules must be measured not only with respect to monofacial silicon modules, but rather with respect to bifacial silicon modules. These have an extra yield, compared with monofacial PV modules of the same efficiency, of approx. 5%-20% depending on the mode of use and site of use;
(ii) small losses in the case of a suboptimally adjusted band gap or voltage at the point of maximum power are possible. As a result, the top cell 3 may be selected with respect to other criteria, such as reliability or efficiency of the top cell;
(iii) the voltage increases, per additional solar cell in a string of solar cells, only by the voltage of the bottom cell and not by the combined voltage of the bottom plus top cell. This allows for more photovoltaic modules per module strand, and thus fewer cables are required in the system design.

As shown in FIGS. 1(c) and 1(d) as a partial view, 3TT solar cells 11 may be integrated into a solar module 19 by a combination of series and parallel connection. Since the top cells 3 generate a significantly higher voltage than the bottom cells 5, e.g. a single top cell 3 is connected in parallel with two bottom cells 5. For this purpose, a top contact 13, i.e. a contact of the top cell 3 facing away from the bottom cell 5, is guided to a contact of the opposing polarity, of the next-but-one 3TT solar cell 11, this being a center tap contact 17.

Since there is no next-but-one 3TT solar cell 11 present at the end of a string, losses occur here in the order of magnitude of the power of one to two 3TT solar cells, depending on the cell design or configuration and/or the manner of the connection. The losses at the ends of the strings have been studied theoretically, for example in document [5] cited in the introduction to the description, and the considerations regarding adjusting the voltage by the connection of the cells have been discussed since the introduction of 3TT solar cells, for example in document [2] cited in the introduction to the description. A possible manner of connection technology for 3T tandem PV modules has been set out in document [10]. Accordingly, a solution that is implementable in practice exists for the connection of 3TT solar cells in the solar module. In this case, it is noted that instead of connecting 3TT solar cells by means of a common connector structure, to which various terminal contacts of the 3TT solar cells may then be connected or wired using different methods, as is described in document [10], alternatively continuous connectors may also be used, by means of which typically adjacent solar cells are contacted and connected within a module, typically one single connector being guided from a front side of a 3TT solar cell to a rear side of a neighboring 3TT solar cell.

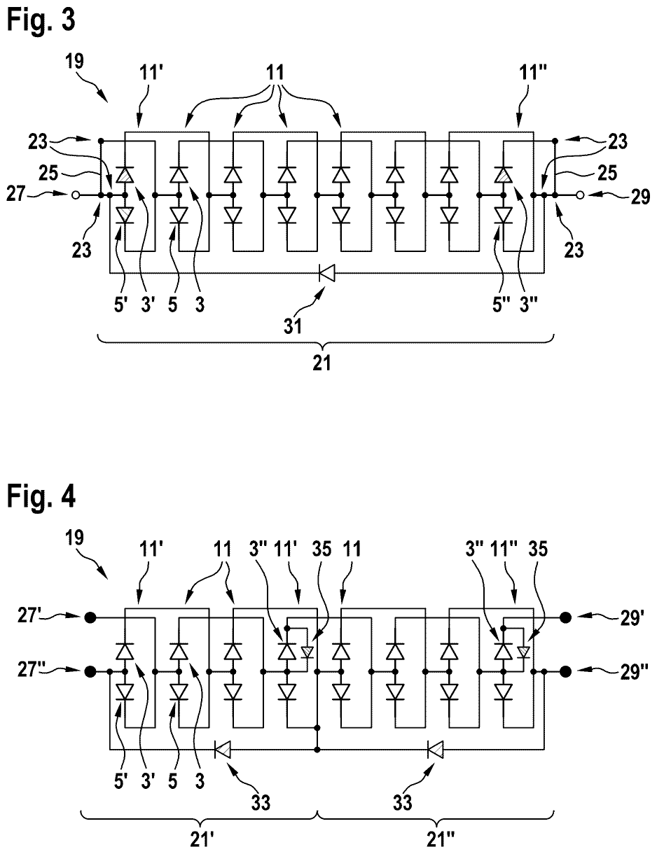

FIG. 3 shows a possible conventional connection of 3TT solar cells 11 in a combination of series and parallel connection for module integration. There are in each case two wiring ends 23 at both ends of a string 21. These are conventionally interconnected by electrical connectors 25, in order to be able to extract the current, generated by the string 21, from the solar module 19 at a current input connection 27 and a current output connection 29. In other words, the connectors 25 at each string end ensure that the current generated in the string 21 may be extracted from the string 21.

However, the bottom cell 5′ of the first 3TT solar cell 11′ of the string 21 (far left in FIG. 3) is short-circuited by said connectors 25, and its power is not extracted. Furthermore, at each string end, i.e. at the first 3TT solar cell 11′ and the last 3TT solar cell 11″, the top cell 3′, 3″ there is operated only at approximately 50% of its voltage. This leads to losses, which are also referred to as string end losses and, in the case shown, are of the magnitude of the power of approximately one 3TT solar cell. The connection of the wiring ends 23 using the connectors 25 furthermore makes it possible to connect a common bypass diode 31 in parallel with all the 3TT solar cells 11 of the string 21, including all the top cells 3 and all the bottom cells 5. This means that string end losses occur upon integration of each bypass diode. In the case of a currently typical string length of 20 cells, this procedure leads to an approximately 5% power loss, which often more than overcompensates for the advantage of the 3TT solar cells relative to e.g. 2TT solar cells. In the case of perovskite solar cells, often even only a small string length per bypass diode is possible, and thus the influence of the end losses is even greater.

The approach discussed in this patent application discusses both methods for transferring the string end losses from a module level (having typically approximately 60 cells) or a sub-string level (typically a ⅓ module having approximately 20 cells) to a system level e.g. of a solar collector (having typically up to 2000 cells), in order to minimize their relative contribution, and also addresses an advantageous option for integration of bypass diodes.

In particular, embodiments of the invention address the following aspects:
(i) an electrical connection between solar modules to form a solar collector with for example one cable having two cores, or with two cables;
(ii) an integration of bypass diodes without a need to bring together contacts or wiring ends at the end of strings;
(iii) a module design for modules in the center and at the ends of strings by the external combination of the contacts (e.g. module contacts which are combined outside of the module), e.g. by suitable plugs or connectors.

FIG. 4 shows an embodiment of a solar module 19 according to the invention, in which 3TT solar cells 11 are wired together and to two current input connections 27′, 27″ and two current output connections 29′, 29″ in a special manner. In this case, furthermore at least one first bypass diode 33 and one second bypass diode 35 are provided in each of two sub-strings 21′, 21″ shown by way of example.

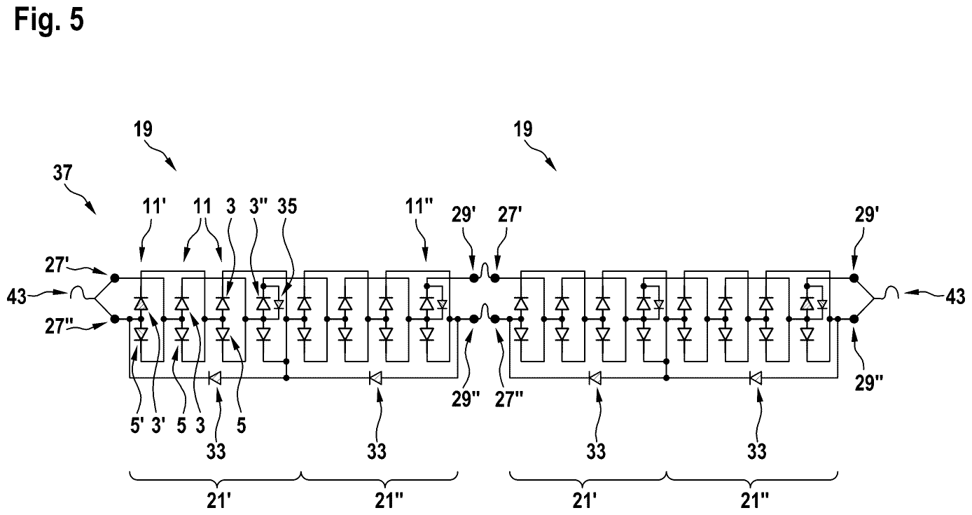

FIG. 5 illustrates how two solar modules 19 according to the invention may be connected to form a solar collector 37 according to the invention. In this case, it is noted that real solar collectors of course generally comprise more than two solar modules 19, but that a principle of the wiring may be clearly identified on the basis of this reduced example.

With regard to the above aspect (i), FIGS. 4 and 5 illustrate leading out all string ends of different potentials to terminal contacts in the form of the two current input connections 27 and current output connections 29 in each case. As a result, the sub-strings 21′, 21″ of a plurality of neighboring solar modules 19 are connected beyond physical limits of the solar modules 1 to form an overall string. The interconnection of the solar modules 19 via the two current input connections 27 and current output connections 29 in each case makes it possible to provide all the top cells 3 in the overall string (with the exception of the top cell 3 of a very last 3TT solar cell 11) with a next-but-one bottom cell 5 in each case, for parallel connection, and to extend the connection concept beyond the module limits. As a result, the string end losses, as would otherwise arise in each of the sub-strings 21′, 21″ in parallel with a bypass diode 31 (i.e. in the case of typically 20 or fewer cells in each case) shift to a system level (having typically up to 2000 or more cells) having a plurality of interconnected solar modules 1, which reduces a relative contribution of the string end losses by two orders of magnitude (i.e. from 1/20=5% to 1/2000=0.05%).

With regard to the above aspect (ii), FIGS. 4 and 5 schematically show the integration of the first bypass diodes 33 and second bypass diodes 35. The first bypass diodes 33 (shown extending at a lower part in the figures) protect the respective sub-string 21′, 21″, similarly to the case of a current 2TT solar cell or single-junction solar cell solar module. In this case, however, the last top cell 3″ of each sub-string 21′, 21″ is not protected, and is therefore protected by a separate second diode 35.

At the end of the entire string, which extends over a plurality of solar modules 19, due to the described connection, the entire string ends 43 must be brought together for connection to power electronics or an inverter in general, in order to allow for dissipation of the generated current from three parallel strings. In this case, a first strand comprises a first plurality of next-but-one top cells 3 in each case, in each case connected in series, a second strand comprises a second plurality of likewise next-but-one other top cells 3 in each case, in each case connected in series, and a third strand comprises a plurality of next bottom cells in each case, in each case connected in series.

It is noted that the examples shown in FIGS. 3 to 5 in each case apply for the case where the voltages Vₜₒₚ generated by the top cells 3 upon illumination are approximately twice those voltages V_{bot} of the bottom cells 5, i.e. a ratio Vₜₒₚ/V_{bot} is a whole-number ratio (m:n), which, in the specific case, is (2:1). Accordingly, the described connection in each case comprises n=1 top cells 3 connected in series, which are connected in parallel with m=2 bottom cells 5 connected in series. In this case, m=2 mutually parallel strands of series-connected top cells 3 are provided.

It is noted that in general the voltage ratios of the top and bottom cells may be adapted to one another (i.e. “matched”) in another manner in whole-number ratios m:n, e.g. Vₜₒₚ/V_{bot}=(m:n)=(3:2) (not shown in the figures).

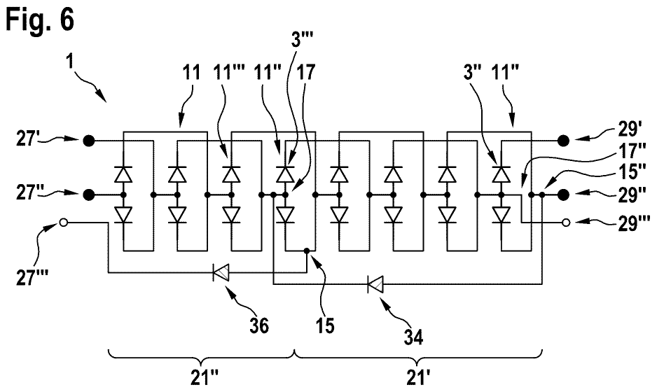

FIG. 6 shows an alternative embodiment of a solar cell module 1 which differs from that of FIGS. 4 and 5 in particular with regard to the provision and connection of bypass diodes and with regard to the way in which this solar cell module 1 is to be connected to neighboring modules.

In particular, said solar cell module 1 comprises a bypass diode 34 connected across strings, in the center of the solar module 19. Said bypass diode is connected on the one hand to a penultimate cell 3TT solar cell 11′″ upstream of the last 3TT solar cell 11″ of the previous neighboring sub-string 21″ and on the other hand to the last solar cell 11″ of the sub-string 21′ to be protected. In the example shown, the bypass diode 34 connected across strings is connected on the one hand to the bottom contact 15 of the penultimate cell 3TT solar cell 11′″ of the previous neighboring sub-string 21″ and on the other hand to the bottom contact 15 of the last solar cell 11″ of the sub-string 21′ to be protected. In this way, the last solar cell 11″ in the previous neighboring sub-string 21″ is connected both to the bypass diode 36 associated with its sub-string 21″ and to the across-string bypass diode 34 associated with the neighboring sub-string 21′. As a result, its top cell 3′″ is also protected, such that a second bypass diode 35, as has been proposed for the embodiment of FIG. 4, may be omitted.

Furthermore, said solar cell module 1 comprises a further current input connection 27′″ in addition to the first and the second current input connection 27′, 27″, and/or a further current output connection 29′″ in addition to the first and the second current output connection 29′, 29″. Furthermore, the solar module 1 comprises at least one bypass diode 36 which is connected such that it may protect both the 3TT solar cells 11 of the solar module 1 in question and at least one 3TT solar cell 11 of a neighboring solar module. Therefore, said bypass diode is also referred to herein as a bypass diode 36 to be connected across modules.

In the example shown, said bypass diode 36 to be connected across modules is brought into electrical contact on the one hand with the further current input connection 27′″ and on the other hand with the bottom contact 15 of one of the 3TT solar cells 11 in the solar module 1.

Furthermore, in addition to the bypass diode 36 to be connected across modules, the overall solar module also comprises a further bypass diode which, as described above, is connected as an across-string bypass diode 34. In this case, said bypass diode 34 is connected between the center tap contact 17 of the 3TT solar cell 11″ of the sub-string 21″ shown on the left in the drawing of which the bottom contact 15 is contacted by the across-module bypass diode 36, and the bottom contact 15″ of the last 3TT solar cell 11″ of the sub-string 21′ shown on the left in the example. Since, however, the top cell 3″ of the last 3TT solar cell 11″ is not protected thereby, the center tap contact 17″ of said last 3TT solar cell 11″ is connected to the further current output connection 29′″.

Since now in each case between neighboring solar modules 1 their further current input connection 27′″ is in each case connected to the further current output connection 29′″ of the neighboring solar module 1, the bypass diode 36 to be connected across modules may also protect the top cell 3″ of the last 3TT solar cell 11″ in the neighboring solar module 1. Therefore, in this embodiment, providing one or more second bypass diodes 35 may be omitted.

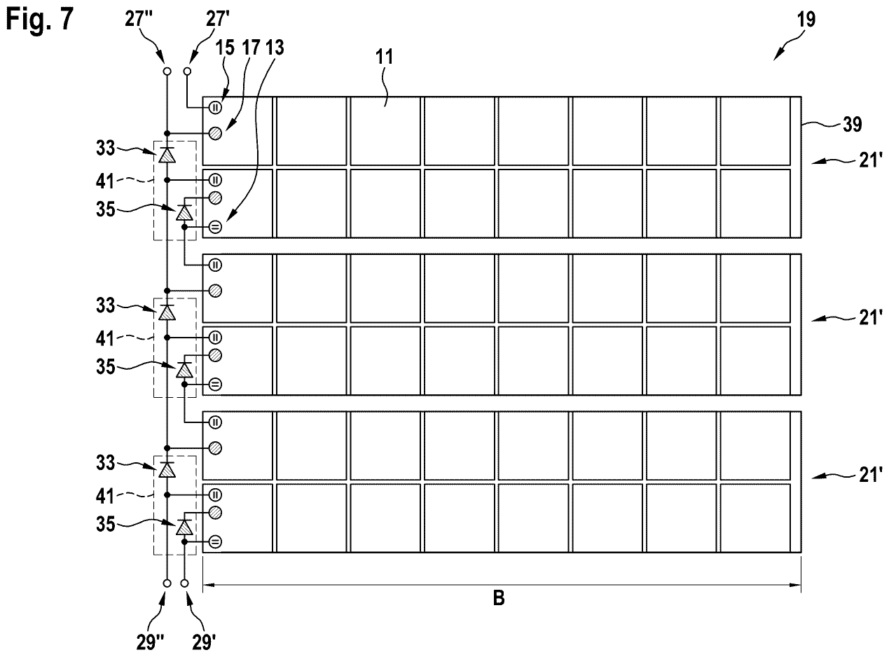

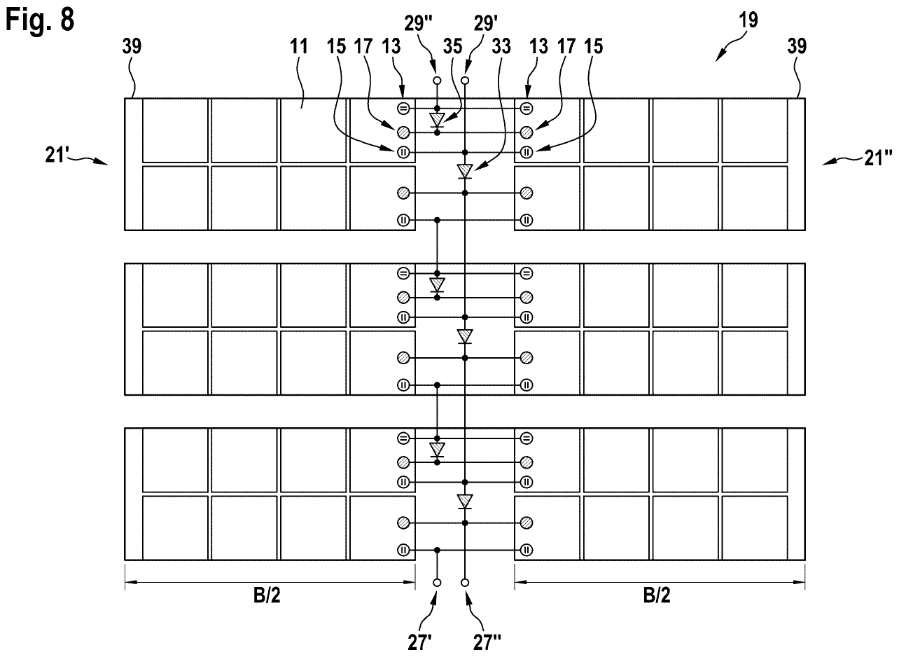

FIGS. 7 and 8 show possible geometric arrangements of the bypass diodes 33, 35 in respective sub-strings 21 of a 3TT solar module 19 for 3TT solar cells 11 having high electric strength (FIG. 7) and low electric strength (FIG. 8).

In this case, in the embodiment shown in FIG. 7, plural 3TT solar cells 11 are arranged laterally side-by-side in rows over an entire width B of the solar module 19, in the example shown two such rows being electrically connected to form a sub-string 21′. In this case, the first bypass diode 33 and the second bypass diode 35 are each arranged laterally beside the sub-string 21′. In this case, for example, the bypass diodes 33, 35 may be arranged close to a lateral edge of the solar module 19, for example at or below a frame (not shown) that encloses the solar module 19.

In the figure, the squares represent the 3TT solar cells 11. The lines 39 along the edge of the 3TT solar cells 11 symbolize a 3-pole connection between the solar cells. A practical solution proposal for this 3-pole connection has been explained in [10]. Vertically hatched points symbolize a bottom contact 15 (R-contact) to the bottom cell 5, horizontally hatched points symbolize a top contact 13 (T-contact) to the top cell 3, diagonally hatched points symbolize a center tap contact 17 (Z-contact) of the 3TT solar cell 11. In order to keep the contact pattern for the bypass diodes 33, 35 simple, only the contacts to the geometrically closest 3TT solar cell 11 in each case are shown. The terminal contacts are guided further to further 3TT solar cells 11 in the string 21 by the connection between the 3TT solar cells 11 (symbolized by the line 39). This arrangement comprises two parallel rows of solar cells, which are connected in series. This geometric arrangement is suitable for solar cells having high reverse electric strength.

In contrast, in the embodiment shown in FIG. 8, plural 3TT solar cells 11 are arranged laterally side-by-side over a first half B/2 of a width B of the solar module 19 and are electrically connected to form a first sub-string 21′, and a plurality of other 3TT solar cells are arranged laterally side-by-side over a second half of the width of the solar module 19 and are electrically connected to form a second sub-string 21″. In this case, the first sub-string 21′ and the second sub-string 21″ are connected in parallel with one another. The first bypass diode 33 and the second bypass diode 35 are each arranged laterally between the first sub-string 21′ and the second sub-string 21″. Such a type of connection is particularly suitable for 3TT solar cells 11 having low reverse electric strength.

In other words, as in the case of half-cell modules, the bypass connection for 3TT solar cells 11 having low reverse electric strength may be made in the center of the module (FIG. 8). However, the 3TT solar cells 11 are connected quasi in series within a double string (symbolized by the peripheral line 39). The contacts led out may furthermore be connected to the next sub-string 21 or to the next solar module 19. A center contact 17 (Z-contact) is tapped by a 3TT solar cell 11 that is not located directly in the module center. Said contact is established via a wired connection, which is guided, as standard, to the next-but-one top cell 3 for further connection. This connection may be used as a current tap.

The particular feature of the geometric arrangement of solar cells 11 and bypass diodes 33, 35 in FIG. 7 is that in each case two of the bypass diodes 33, 35 located beside a double string 21 may be combined in a common diode box 41 (shown dashed in FIG. 7 for reasons of improved overview). It is thus possible, for example, to construct a solar module 19 with the conventional three diode boxes 41. Likewise, in the geometric arrangement of solar cells 11 and bypass diodes 33, 35 in FIG. 8 in each case two bypass diodes 33, 35 may be connected in one diode box (not shown in FIG. 8 for reasons of improved overview), and therefore it is again possible to carry out the diode connection with the conventional three diode boxes 41 in the module center.

If the proposed solar modules 19 are connected, it is optionally possible, accepting string-end losses, to short-circuit the two current output connections 29′, 29″ to a common negative contact and the two current input connections 27′, 27″ to a common positive contact, in order to achieve only a single-core connection between the solar modules 19. In this case, the solar modules 19 are wired together in series in such a way that in each case the negative contact is connected to a positive contact of a neighboring solar module 19. If it is wished to make use of the entire potential of the connection, a first current output connection 29′must be connected in series to a first current input connection 27′, and a second current output connection 29″ to a second current input connection 27″ of a neighboring solar module 19 via a two-core connection, i.e. for example using a two-core cable or using two cables.

It is noted that terms such as “comprising,” “having,” etc. do not exclude any other elements or steps, and terms such as “a” or “an” do not exclude a plurality. Furthermore, it is noted that features or steps that have been described with reference to one of the above embodiments may also be used in combination with other features or steps of other embodiments described above. Reference signs in the claims are not to be considered limiting.

### LIST OF REFERENCE SIGNS

1 tandem solar cell
3 top cell
3′ top cell of the first 3TT solar cell
3″ top cell of the last 3TT solar cell
5′ bottom cell of the first 3TT solar cell
5″ in bottom cell of the last 3TT solar cell
5 bottom cell
7 2TT solar cell
9 4TT solar cell
11 3TT solar cell
11′ first 3TT solar cell
11″ last 3TT solar cell
13 top contacts
15 bottom contact
17 center tap contact
19 solar module
21 string
21′ sub-string
21″ sub-string
23 wiring ends
25 connector
27 current input connection
27′ first current input connection
27″ second current input connection
27′″ further current input connection
29 current output connection
29′ first current output connection
29″ second current output connection
29′″ further current output connection
31 common bypass diode
33 first bypass diode
34 bypass diode connected across strings
35 second bypass diode
36 bypass diode to be connected across modules
37 solar collector
39 line symbolizing series connection
41 diode box
43 entire string ends

1-17. (canceled)

18. A solar module, comprising:
a plurality of 3-terminal tandem (3TT) solar cells which are interconnected to form at least one string, and
at least two current input connections at a current input of the solar module and/or at least two current output connections at a current output of the solar module,
wherein each 3TT solar cell has a stack with a top cell and a bottom cell arranged below it, wherein the top cell and the bottom cell differ from one another in terms of an electrical voltage generated when exposed to light,
wherein each 3TT solar cell has three terminal contacts with a top contact, which makes electrical contact with a side of the top cell facing away from the bottom cell, a bottom contact, which makes electrical contact with a side of the bottom cell facing away from the top cell, and a center tap contact, which makes electrical contact with the 3TT solar cell at an interface between the top cell and the bottom cell,
wherein a first of the current input connections is connected to at least one of the terminal contacts of a first of the 3TT solar cells closest to the current input, and wherein a second of the current input connections is connected to at least one of the terminal contacts of a second of the 3TT solar cells neighboring the first 3TT solar cell, and/or
wherein a first of the current output connections is connected to at least one of the terminal contacts of a last of the 3TT solar cells closest to the current output, and wherein a second of the current output connections is connected to at least one of the terminal contacts of a penultimate of the 3TT solar cells neighboring the last 3TT solar cell,
wherein
(i) wherein in each of the strings a first bypass diode is connected in parallel with the 3TT solar cells of the string and wherein furthermore, in each of the strings, a second bypass diode is connected in parallel with the top cell and/or bottom cell of a last 3TT solar cell of the string, and/or
(ii) wherein the solar module has at least one bypass diode which is connected across strings, wherein the bypass diode which is connected across strings is connected on the one hand to a 3TT solar cell upstream of the last 3TT solar cell of a neighboring sub-string and on the other hand to the last solar cell of the sub-string to be protected.

19. The solar module according to claim 18,
wherein the top cell and the bottom cell of each of the 3TT solar cells are arranged in an r-type configuration in reverse polarity, and
wherein the first current input connection is connected to the center tap contact of the first 3TT solar cell and the second current input connection is connected to the center tap contact of the second solar cell, and/or
wherein the first current output connection is connected to the top contact of the last 3TT solar cell and the second current output connection is connected to the top contact of the penultimate 3TT solar cell.

20. The solar module according to claim 18,
wherein the electrical voltage of the top cell generated when exposed to light, and the electrical voltage of the bottom cell generated when exposed to light, are substantially in a ratio of m to n, where m and n are natural numbers, and
wherein in each case n top cells connected in series are connected in parallel with m bottom cells connected in series.

21. The solar module according to claim 20,
wherein m≥2 and wherein n≥1, and
wherein a number of the current input connections and/or a number of the current output connections are equal to or greater than a larger of the two values n and m.

22. The solar module according to claim 20,
wherein m=2 and n=1,
wherein, with the exception of the last 3TT solar cell, each bottom contact of a 3TT solar cell is connected to the center tap contact of the neighboring next 3TT solar cell, and
wherein, with the exception of the last and the penultimate 3TT solar cell, each top contact of a 3TT solar cell is connected to the center tap contact of the next but one following 3TT solar cell.

23. The solar module according to claim 18,
wherein in each of the strings a first bypass diode is connected in parallel with the 3TT solar cells of the string and wherein furthermore, in each of the strings, a second bypass diode is connected in parallel with the top cell and/or bottom cell of a last 3TT solar cell of the string, and
wherein the first bypass diode is electrically connected on the one hand to the center tap contact of a first 3TT solar cell of the string and on the other hand to the bottom contact or the top contact of the last 3TT solar cell of the string, and
wherein the second bypass diode is electrically connected on the one hand to the top contact or the bottom contact of the last 3TT solar cell of the string and on the other hand to the center tap contact of the last 3TT solar cell of the string.

24. The solar module according to claim 18,
wherein the solar module has at least one further current input connection and/or at least one further current output connection,
wherein at least one bypass diode to be connected across modules is received in the solar module,
wherein the bypass diode to be connected across modules is connected on the one hand to the further current input connection and on the other hand to one of the terminal contacts, in particular to the bottom contact, of one of the 3TT solar cells in the solar module, and/or
wherein the center tap contact of the last 3TT solar cell of the solar module is connected to the further current output connection.

25. The solar module according to claim 18,
wherein plural 3TT solar cells are arranged laterally side-by-side over an entire width (B) of the solar module and are electrically connected to form a sub-string, and
wherein the first bypass diode and, optionally, the second bypass diode are each arranged laterally beside the sub-string.

26. The solar module according to claim 18,
wherein plural 3TT solar cells are arranged laterally side-by-side over a first half of a width (B) of the solar module and are electrically connected to form a first sub-string, and a plurality of 3TT solar cells are arranged laterally side-by-side over a second half of the width of the solar module and are electrically connected to form a second sub-string, wherein the first sub-string and the second sub-string are connected in parallel with one another, and
wherein the first bypass diode and, optionally, the second bypass diode are each arranged between the first sub-string and the second sub-string.

27. The solar module according to claim 18,
wherein the first and the second bypass diode are received in a common diode box.

28. The solar module according to claim 18,
wherein the top cell is a perovskite solar cell and the bottom cell is a silicon solar cell.

29. The solar module according to claim 18,
wherein the bottom solar cell is a rear contact solar cell, in which terminal contacts of both polarities are arranged interdigitated on a rear side of the bottom solar cell facing away from the top solar cell, and wherein one of the terminal contacts of the bottom solar cell acts as the center tap contact.

30. The solar collector, comprising:
a plurality of solar modules according to claim 18,
wherein in the case of neighboring solar modules in each case each of the current output connections of one of the solar modules is electrically connected to an associated one of the current input connections of the neighboring one of the solar modules.

31. The solar collector according to claim 30,
wherein, with the exception of the current input connections of a first of the solar modules and the current output connections of a last of the solar modules, the current input connections of each of the solar modules are electrically isolated from one another and the current output connections of each of the solar modules are electrically isolated from one another.

32. The solar collector according to claim 30,
wherein in the case of a first of the solar modules the at least two current input connections are electrically short-circuited with one another or interconnected, and/or wherein in the case of a last of the solar modules the at least two current output connections are electrically short-circuited with one another or interconnected.
